(19) United States
(12) Patent Application Publication
(10) Pub. No.: US 2025/0351950 A1
(43) Pub. Date: Nov. 20, 2025

(54) BRUSH CLEANING EQUIPMENT

(71) Applicant: Samsung Electronics Co., Ltd., Suwon-si (KR)

(72) Inventors: Wan Su SONG, Suwon-si (KR); Dong Hoon KWON, Suwon-si (KR)

(73) Assignee: Samsung Electronics Co., Ltd., Suwon-si (KR)

(21) Appl. No.: 18/959,887

(22) Filed: Nov. 26, 2024

(30) Foreign Application Priority Data
May 14, 2024 (KR) 10-2024-0062983

(51) Int. Cl. A46B 17/06; A46B 13/02; B08B 7/00; B24C 1/00

(52) U.S. Cl. CPC A46B 17/06; A46B 13/02; B08B 7/00; B24C 1/003

(57) ABSTRACT

Brush cleaning equipment may include a rotating unit configured to rotate a brush core extending in a first direction, a plate on one side of the brush core and configured to rub against a surface of a brush along a periphery of the brush core in response to the rotation of the brush core, and a cleaning material supply unit on the other side of the brush core opposite to the plate in a second direction intersecting the first direction, and the cleaning material supply unit configured to supply a cleaning material onto a surface of the brush, wherein the cleaning material supply unit includes a main body including a cavity configured to carry the cleaning material, and a nozzle combined with the main body, the nozzle configured to receive the cleaning material from the main body and spray the cleaning material onto the surface of the brush.

### CROSS-REFERENCE TO RELATED APPLICATION

This application claims priority from Korean Patent Application No. 10-2024-0062983 filed on May 14, 2024 in the Korean Intellectual Property Office, and all the benefits accruing therefrom under 35 U.S.C. 119, the contents of which in its entirety are incorporated herein by reference.

### BACKGROUND

The present disclosure relates to brush cleaning equipment.

A number of stages processes are performed to form a desired pattern on a surface of a semiconductor wafer. Unnecessary thin films and various contaminants are formed and remain on the surface of the semiconductor wafer in which a certain process is performed. The semiconductor wafer needs to be cleaned to remove them.

In particular, when a planarization process is performed on a semiconductor wafer using a chemical mechanical polishing (CMP) device, colloidal abrasives contained in a polishing slurry are present on the semiconductor wafer. Therefore, after the CMP process is performed, a cleaning process needs to be performed to remove the abrasive particles that are aggregated before performing the subsequent process.

Scrubber cleaning which is a method of cleaning while rotating a brush is mainly used as the cleaning process. The brush may have nodules on its outer surface to help clean the wafer. The rotating cylindrical brush needs to be meshed with a rotating circular wafer such as a semiconductor wafer. At this time, the particles removed from the semiconductor wafer surface may be adsorbed again onto the surface of the brush again. When the amount of contaminants adsorbed onto the surface of the brush increases by a certain amount or more while the scrubber cleaning process is being repeated, a reverse contamination in which the contaminants on the brush surface contaminate the semiconductor wafer again may occur. Accordingly, there is a need for a process of efficiently cleaning the brush surface.

### SUMMARY

Aspects of the present disclosure provide a brush cleaning equipment that effectively removes contaminants adsorbed onto the surface to prevent or reduce in likelihood damage to the semiconductor wafer.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to some aspects of the present disclosure, there is a provided a brush cleaning equipment comprising a rotating unit configured to rotate a brush core extending in a first direction, a plate on one side of the brush core and configured to rub against a surface of a brush along a periphery of the brush core in response to rotation of the brush core, and a cleaning material supply unit on an other side of the brush core opposite to the plate in a second direction intersecting the first direction, the cleaning material supply unit configured to supply a cleaning material onto the surface of the brush, wherein the cleaning material supply unit includes a main body including a cavity configured to carry the cleaning material, and a nozzle combined with the main body, the nozzle configured to receive the cleaning material from the main body and spray the cleaning material onto the surface of the brush.

According to some aspects of the present disclosure, there is a provided a brush cleaning equipment comprising a rotating unit configured to rotate a brush core extending in a first direction, a plate including a first surface and a second surface opposite each other in a second direction intersecting the first direction, the plate is configured to rub against a surface of a brush along a periphery of the brush core in response to the brush core rotating, and a cleaning material supply unit on the second surface, the cleaning material supply unit configured to supply a cleaning material onto the surface of the brush, wherein the brush is on the first surface, the plate defines a hole extending from the first surface to the second surface, the cleaning material supply unit includes a main body having a cavity configured to carry the cleaning material, the cavity on the second surface, and a nozzle configured to receive the cleaning material from the main body and spray the cleaning material onto the surface of the brush, the nozzle includes a nozzle arm combined with the main body, and a nozzle tip combined with the nozzle arm, and the nozzle is configured to spray the cleaning material onto the surface of the brush through the hole.

According to some aspects of the present disclosure, there is a provided a brush cleaning equipment comprising a rotating unit configured to rotate a brush core extending in a first direction; a plate on one side of the brush core, the plate configured to rub against a surface of a brush along a periphery of the brush core in response to the brush core rotating; a guide rail extending in the first direction, the guide rail on an other side of the brush core opposite to the plate in a second direction intersecting the first direction; and a cleaning material supply unit configured to supply a cleaning material to the surface of the brush, wherein the cleaning material supply unit includes, a main body configured to move along the guide rail, the main body including a cleaning material generating unit, a container configured to carry the cleaning material inside, and a pressurizing unit configured to pressurize the cleaning material carried into the container with pressurized gas; and a nozzle combined with the main body, the nozzle configured to receive the cleaning material from the container and spray the cleaning material onto the surface of the brush.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail some example embodiments thereof with reference to the attached drawings, in which:

FIGS. 1 to 3 are diagrams for explaining the brush cleaning equipment, according to some example embodiments.

FIG. 4 is a diagram for explaining the cleaning of the wafer, using the brush of FIG. 1.

FIG. 5 is a diagram for explaining the cleaning of the brush, using the brush cleaning equipment of FIG. 1.

FIG. 6 is a diagram for explaining the brush cleaning equipment, according to some example embodiments.

FIG. 7 is a diagram for explaining the brush cleaning equipment, according to some example embodiments.

FIG. 8 is a diagram for explaining a brush cleaning equipment, according to some example embodiments.

FIG. 9 is a diagram for explaining a brush cleaning equipment, according to some example embodiments.

FIG. 10 is a diagram for explaining a brush cleaning equipment, according to some example embodiments.

FIGS. 11 and 12 are diagrams for explaining a brush cleaning equipment, according to some example embodiments.

FIG. 13 is a diagram for explaining a brush cleaning equipment, according to some example embodiments.

FIGS. 14 and 15 are diagrams for explaining a brush cleaning equipment, according to some example embodiments.

FIG. 16 is a diagram for explaining a brush cleaning equipment, according to some example embodiments.

FIG. 17 is a diagram for explaining a brush cleaning equipment, according to some example embodiments.

FIG. 18 is a diagram for explaining a brush cleaning equipment, according to some example embodiments.

FIGS. 19 and 20 are diagrams for explaining a brush cleaning equipment, according to some example embodiments.

### DETAILED DESCRIPTION

Hereinafter, a brush cleaning equipment according to some example embodiments will be described with reference to the accompanying drawings. The same reference numerals are used for the same components in the drawings, and the repeated description thereof will not be provided. In the following description, an upper part or an upper surface may be based on a third direction D3, and a lower part or a lower surface may be based on a direction opposite to the third direction D3. In addition, a first direction D1, a second direction D2, and the third direction D3 may be perpendicular to one another.

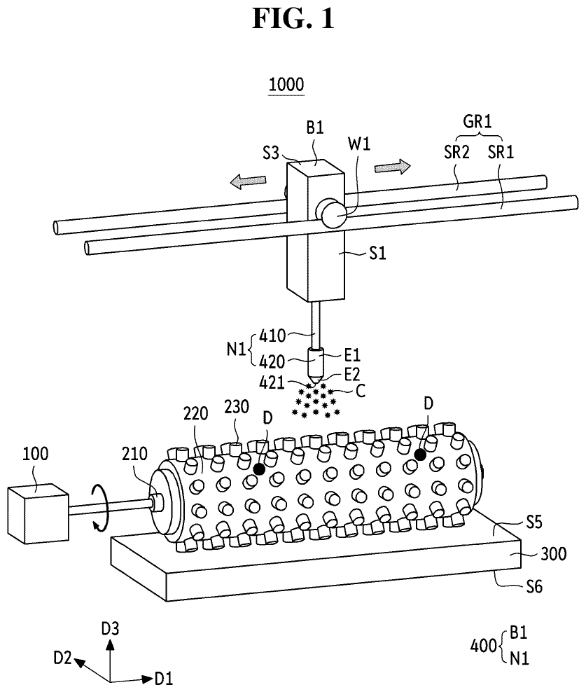

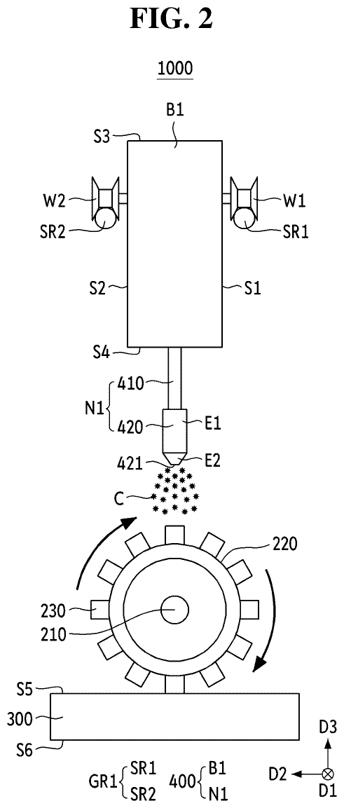

FIGS. 1 to 3 are diagrams for explaining the brush cleaning equipment according to some example embodiments. Hereinafter, the brush cleaning equipment according to some example embodiments will be described with reference to FIGS. 1 to 3.

Referring to FIG. 1, a brush cleaning equipment 1000 may include a rotating unit 100, a plate 300, and a cleaning material supply unit 400.

The brush cleaning equipment 1000 may be equipment for cleaning a brush 220 used in a process for cleaning a wafer after a CMP (Chemical Mechanical Polishing) process is performed on the wafer. The brush 220 may be disposed along the periphery of a brush core 210 that extends long in the first direction D1. The brush 220 and the brush core 210 may each extend in the first direction D1. The brush 220 and the brush core 210 may each have a cylindrical shape. An inner surface of the brush 220 may be formed along the profile of the surface of the brush core 210. Accordingly, the brush 220 may be fixed to the brush core 210. However, the above-mentioned method of fixing the brush 220 is an example according to the present disclosure, and the present disclosure is not limited thereto.

The brush 220 may include a plurality of nodules 230. Each nodule 230 may be disposed on the surface of the brush 220. A process for cleaning a wafer using the brush 220 will be described below with reference to FIGS. 1-3.

The rotating unit 100 may be configured to rotate the brush core 210 extending long in the first direction D1. The rotating unit 100 may be connected to the brush core 210. The rotating unit 100 may provide rotational power to the brush core 210. The rotational power provided to the brush core 210 may be transferred to the brush 220 that comes into contact with the brush core 210. Thus, the brush 220 may receive the rotational power provided from the rotating unit 100 and rotate with the first direction D1 as an axis.

The plate 300 may include a first surface S5 and a second surface S6 that are opposite to each other in the third direction D3. The first surface S5 may be an upper surface of the plate 300, and the second surface S6 may be a lower surface of the plate. The first surface S5 may be disposed to face the cleaning material supply unit 400, and the second surface S6 may be disposed to be opposite to the cleaning material supply unit 400. The plate 300 may be disposed on one side of the brush core 210. The plate 300 may be disposed on a plane perpendicular to the third direction D3, and may include a plate-like form. The plate 300 may include, but not limited to, a quartz plate. The plate 300 may include an upper surface for rubbing the surface of the brush 220 and mechanically detaching contaminants on the surface of the brush 220. For example, when the brush 220 rotates on the basis of the rotational power provided by the rotating unit 100, the surface of the brush 220 may be scrubbed against the upper surface of the plate 300. In this manner, the upper surface of the plate 300 may rub against the surface of the brush 220, thereby mechanically removing contaminants on the surface of the brush 220.

The cleaning material supply unit 400 may be disposed on the other side of the brush core 210 to be opposite to the plate 300 in the third direction D3 with the brush core 210 interposed between them. The cleaning material supply unit 400 may be configured to supply the cleaning material C to the surface of the brush 220. For example, the cleaning material supply unit 400 may provide the cleaning material C to the surface of the brush 220, while the brush 220 rotates and the surface of the brush 220 rubs against the upper surface of the plate 300. The cleaning material C may include a gas that sublimes at room temperature. The cleaning material C may also include dry ice pellets. However, the type of the cleaning material C is not limited thereto.

The cleaning material supply unit 400 may include a main body B1 and a nozzle N1. The main body B1 may include a first surface S1 and a second surface S2 that are opposite to each other in the second direction D2. The main body B1 may include a third face S3 and a fourth face S4 that are opposite to each other in the third direction D3. The third face S3 may be the upper surface of the main body B1, and the fourth face S4 may be the lower surface of the main body B1. The main body B1 may include a cavity C1 into which the cleaning material C is carried. The nozzle N1 may be combined with the main body B1 and may be configured to receive the cleaning material C from the main body B1 and spray it onto the surface of the brush 220. The nozzle N1 may be combined with the fourth face S4 and extend in the third direction D3. The nozzle N1 may include a nozzle arm 410 and a nozzle tip 420. The nozzle arm 410 may be combined with the main body B1. The nozzle tip 420 may include a first end E1 that is combined with the nozzle arm 410, and a second end E2 in which an outlet 421 through which the cleaning material C flows out is formed. The outlet 421 may be formed in a longitudinal direction of the nozzle tip 420. The outlet 421 may be disposed to face the surface of the brush 220.

The cavity C1 of the main body B1 may include a cleaning material generating unit 401, a container 402, and a pressurizing unit 403. The cleaning material generating unit 401 may generate the cleaning material C and provide it to the container 402. The container 402 may receive the cleaning material C from the cleaning material generating unit 401, and store it therein. The pressurizing unit 403 may pressurize the cleaning material C carried into the container 402, using a pressurized gas. For example, the pressurizing unit 403 may include a pressurized gas therein. The pressurizing unit 403 may apply a predetermined or alternatively desired pressure to the cleaning material C carried into the container 402, using the pressurized gas. As a result, the cleaning material C carried into the container 402 may be pressurized and moved to the nozzle N1, and the cleaning material C may be sprayed from the nozzle N1 and provided onto the surface of the brush 220. The pressurized gas may be, for example, but not limited thereto, nitrogen (N2) gas.

The brush cleaning equipment 1000 may include a guide rail GR1. The guide rail GR1 may extend long in the first direction D1. The main body B1 may be combined with the guide rail GR1, and the guide rail GR1 may provide a guide so that the main body B1 may move along the guide rail GR1 in the first direction D1 and in the direction opposite to the first direction D1. For example, the guide rail GR1 may include a first sub-guide rail SR1 and a second sub-guide rail SR2. The first sub-guide rail SR1 and the second sub-guide rail SR2 may each extend long in the first direction D1, and may be disposed to be spaced apart from each other in the second direction D2.

The main body B1 may include a first wheel W1 and a second wheel W2. The first wheel W1 may be mounted on the first surface S1, and the second wheel W2 may be mounted on the second surface S2. The first wheel W1 may correspond to the first sub-guide rail SR1, and the second wheel W2 may correspond to the second sub-guide rail SR2. For example, the first wheel W1 may be configured to rotate along the first sub-guide rail SR1, and the second wheel W2 may be configured to rotate along the second sub-guide rail SR2. Accordingly, the main body B1 may move along the first direction D1 and the direction opposite to the first direction D1.

In this way, while the cleaning material supply unit 400 disposed on the upper part of the brush 220 moves freely along the guide rail GR1 to the first direction D1 and the direction opposite to the first direction D1, the cleaning material C may be evenly sprayed onto the surface of the brush 220.

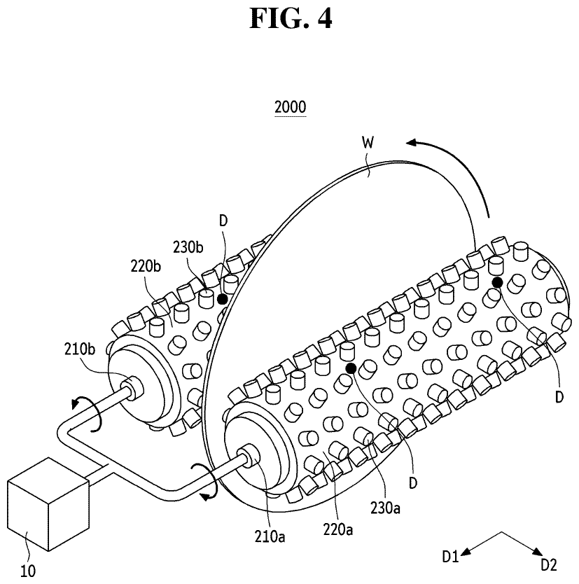

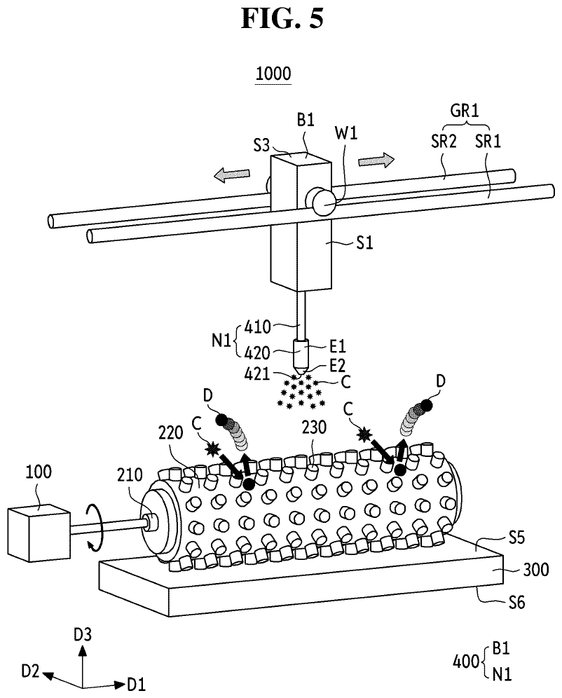

FIG. 4 is a diagram for explaining the cleaning of the wafer, using the brush of FIG. 1. FIG. 5 is a diagram for explaining the cleaning of the brush, using the brush cleaning equipment of FIG. 1.

First, referring to FIG. 4, a wafer cleaning apparatus 2000 may include a brush driving unit 10, brush cores 210a and 210b, and brushes 220a and 220b. The wafer cleaning apparatus 2000 may be an apparatus for cleaning the wafer W after a CMP process is performed on the wafer W. Each of the brushes 220a and 220b may correspond to the brush 220 of FIG. 1, and each of the brush cores 210a and 210b may correspond to the brush core 210 of FIG. 1. Nodules 230a and 230b disposed on the surfaces of each of the brushes 220a and 220b may correspond to the nodules 230 of FIG. 1.

The brush driving unit 10 may transfer the rotational power of the motor to the brush cores 210a and 210b. As a result, the brush cores 210a and 210b may each rotate around the first direction D1 as a central axis. In addition, the brushes 220a and 220b which come into contact with each of the brush cores 210a and 210b may rotate with the first direction D1 as a central axis.

The brushes 220a and 220b may each extend long in the first direction D1, and may be disposed to be spaced apart from each other in the second direction D2. When cleaning the wafer W, the wafer W may be inserted between the brushes 220a and 220b. The surface of the wafer W may come into contact with the brushes 220a and 220b. Specifically, the surface of the wafer W may come into contact with the nodules 230a and 230b formed on the surfaces of each of the brushes 220a and 220b. While cleaning the wafer W, the brushes 220a and 220b may rotate around axes extending in the first direction D1. At the same time, the wafer W may rotate around an axis extending in the second direction D2 that intersects the first direction D1. As a result, the surface of the wafer W may be cleaned by coming into contact with each of the nodules 230a and 230b formed on the surfaces of the brushes 220a and 220b. The wafer cleaning apparatus 2000 may further include other components in addition to the components shown in FIG. 4.

When contaminants remaining on the surface of the wafer W are removed using the brushes 220a and 220b, the contaminants detached from the surface of the wafer W may be adsorbed onto the surfaces of the brushes 220a and 220b. As the wafer cleaning process using the brushes 220a and 220b are continuously performed, the contaminants adsorbed onto the surfaces of the brushes 220a and 220b may be retransferred to the surface of the wafer W. This may cause reverse contamination or defects on the surface of the wafer W.

Referring to FIG. 5, the surface of the brush 220 may be rubbed against the plate 300 to mechanically detach the contaminants D adsorbed onto the surface of the brush 220, and at the same time, the cleaning material C may be supplied to the surface of the brush 220, using the cleaning material supply unit 400. The cleaning material C sprayed onto the surface of the brush 220 may collide with the contaminant D adsorbed onto the surface of the brush 220 to remove the contaminant D. In addition, in some example embodiments in which the cleaning material C includes a material that sublimates at room temperature, such as dry ice pellets, the cleaning material C may sublimate after colliding with the contaminant D, and thus, may not leave by-products on the surface of the brush 220.

The repeated description of the above example embodiments will not be provided and differences will be mainly described.

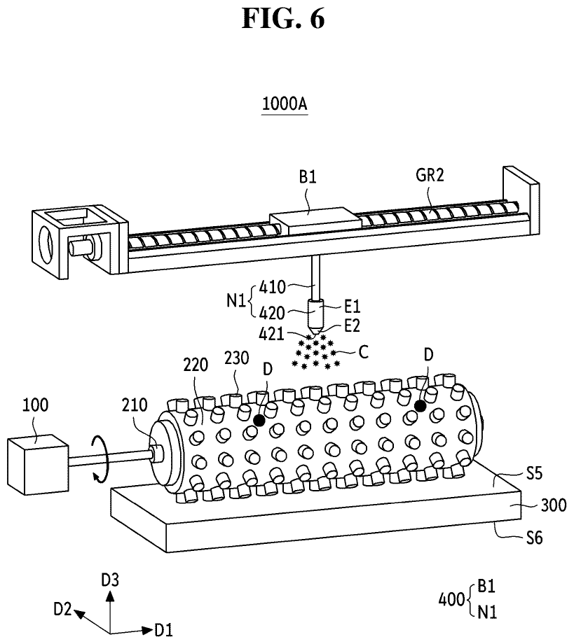

FIG. 6 is a diagram for explaining the brush cleaning equipment according to some example embodiments.

Referring to FIG. 6, a brush cleaning equipment 1000A may include a rotating unit 100, a plate 300, a cleaning material supply unit 400, and a guide rail GR2. The guide rail GR2 may extend long in the first direction D1. A main body B1 may be combined with the guide rail GR2, and the guide rail GR2 may provide a guide that allows the main body B1 to move along the guide rail GR2 in the first direction D1 and in the direction opposite to the first direction D1. The guide rail GR2 may be implemented as a ball screw type. The main body B1 may be configured to be movable in the first direction D1 and the direction opposite to the first direction D1 by being combined with the ball screw type guide rail GR2. This allows the cleaning material C to be uniformly sprayed onto the surface of the brush 220.

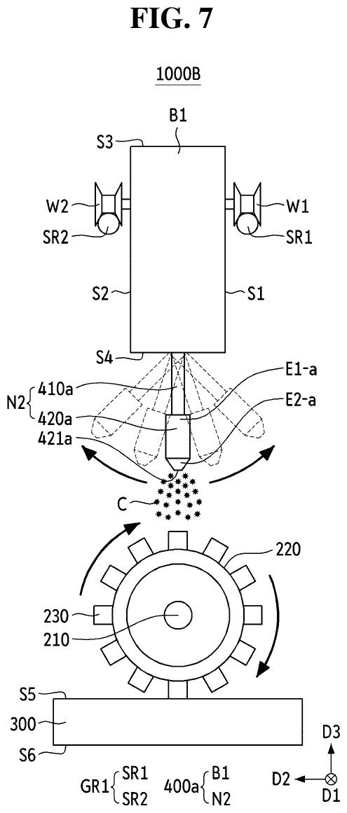

FIG. 7 is a diagram for explaining the brush cleaning equipment according to some example embodiments.

Referring to FIG. 7, a brush cleaning equipment 1000B may include a cleaning material supply unit 400a, and the cleaning material supply unit 400a may include a main body B1 and a nozzle N2. The nozzle N2 may include a nozzle arm 410a and a nozzle tip 420a. The nozzle arm 410a may be combined with the main body B1. The nozzle tip 420a may include a first end E1-a combined with the nozzle arm 410a, and a second end E2-a in which an outlet 421a through which the cleaning material C flows out is formed. The outlet 421a may be formed in the longitudinal direction of the nozzle tip 420a. The outlet 421a may be disposed to face the surface of the brush 220.

The nozzle N2 may be rotatably combined with the main body B1. The nozzle N2 may be combined with the main body B1 to be rotatable in various directions (e.g., the D1 or D2 directions). For example, the nozzle arm 410a may be flexibly combined with the main body B1 by a configuration being disposed inside the main body B1.

In this way, as the nozzle N2 is rotatably combined with the main body B1, an angle at which the cleaning material C sprayed from the nozzle N2 collides with the surface of the brush 220 may be freely adjusted. This allows the cleaning material C to be targeted and sprayed to a region in which contaminants are adsorbed among regions of the surface of the brush 220.

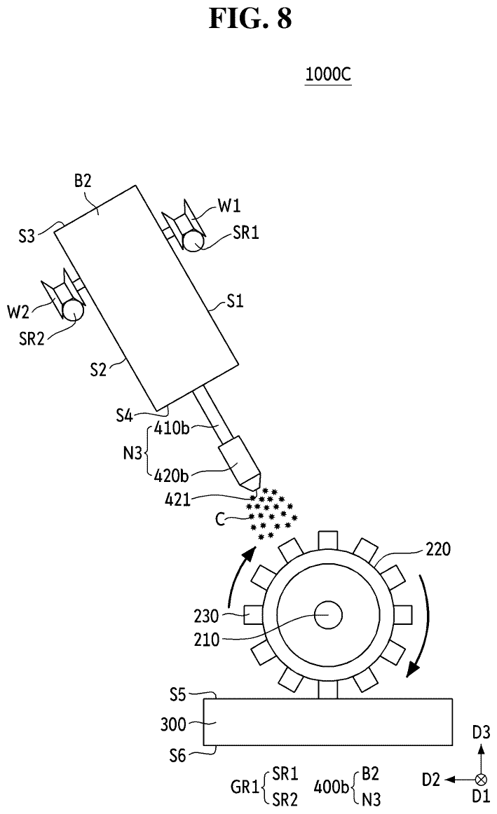

FIG. 8 is a diagram for explaining a brush cleaning equipment according to some example embodiments.

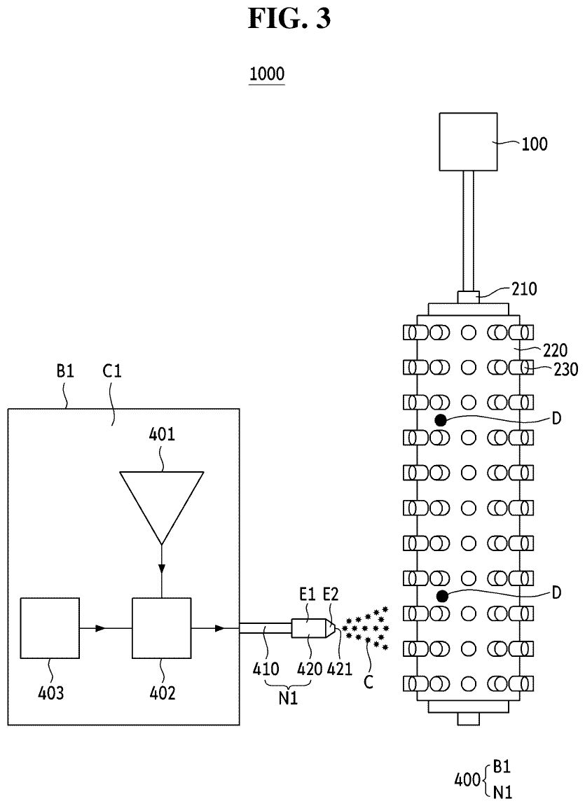

Referring to FIG. 8, a brush cleaning equipment 1000C may include a cleaning material supply unit 400b. The cleaning material supply unit 400b may include a main body B2 and a nozzle N3. The main body B2 may include a cleaning material generating unit 401 (shown in FIG. 3), a container (402 shown in FIG. 3), and a pressurizing unit 403 (shown in FIG. 3) inside, like the main body B1 (shown in FIG. 3). Unlike the example embodiments of FIG. 1 in which the cleaning material supply unit 400 is disposed above the brush core 210 in a direction perpendicular to the first surface S5 of the plate 300, the cleaning material supply unit 400b may be disposed obliquely with respect to the first surface S5 of the plate 300. For example, as shown in FIG. 8, the cleaning material generating unit 400b may be disposed obliquely above the brush core 210 so that an angle formed between the longitudinal direction of the nozzle N3 and the first surface S5 is between 0 degrees and 90 degrees. That is, the longitudinal direction of the nozzle N3 may be included between the second direction D2 and the third direction D3.

In this way, because the cleaning material supply unit 400b is disposed on the side face of the brush core 210 so that the nozzle N3 and the upper surface of the plate 300 form a predetermined or alternatively desired angle, the cleaning material C may be targeted and sprayed onto the region in which the contaminants are adsorbed among the regions of the surface of the brush 220.

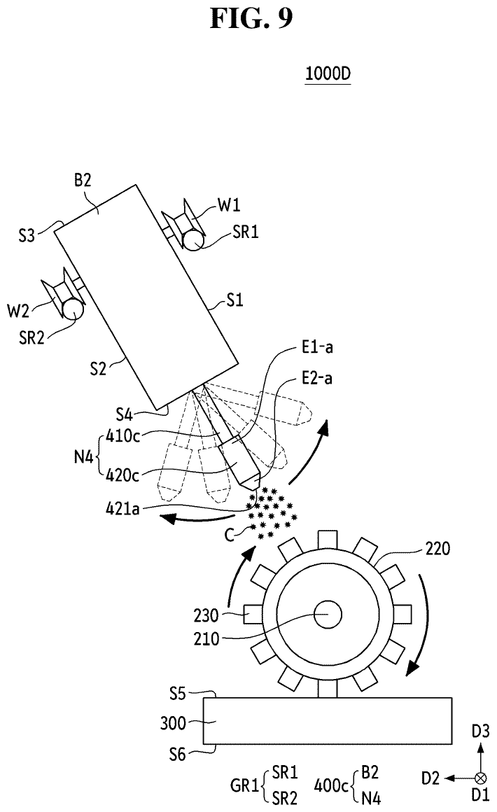

FIG. 9 is a diagram for explaining a brush cleaning equipment according to some example embodiments.

Referring to FIG. 9, a brush cleaning equipment 1000D may include a cleaning material supply unit 1000D. The cleaning material supply unit 1000D may include a main body B2 and a nozzle N4. The nozzle N4 may include a nozzle arm 410c and a nozzle tip 420c. The nozzle N4 may be rotatably combined with the main body B2. For example, the nozzle N4 may be combined with the main body B2 to be rotatable in various directions (e.g., the D1, D2, or D3 direction). For example, the nozzle arm 410c may be flexibly combined with the main body B2 by a configuration disposed inside the main body B2.

In this way, because the main body B2 is disposed on the side face of the brush core 210 to form an oblique angle with respect to the first surface S5 of the plate 300, and the nozzle N4 that is rotatable in various directions is combined with the main body B2, the cleaning material C may be targeted and sprayed onto a region in which the contaminants are adsorbed, among the regions of the surface of the brush 220.

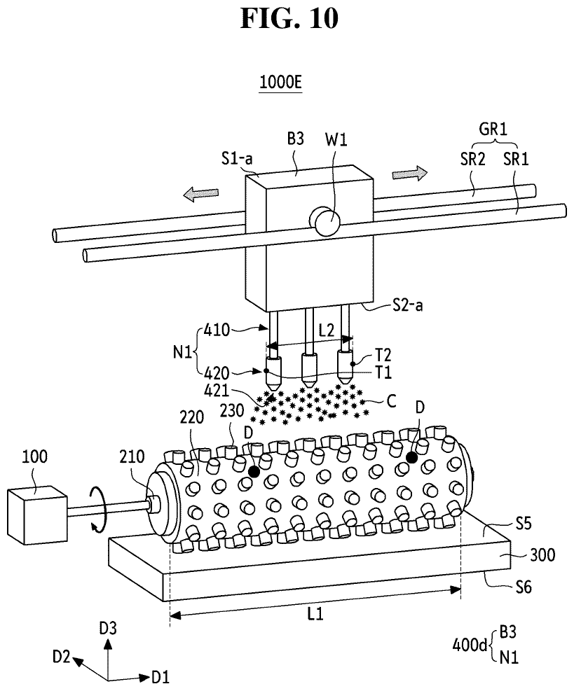

FIG. 10 is a diagram for explaining a brush cleaning equipment according to some example embodiments.

Referring to FIG. 10, a brush cleaning equipment 1000E may include a rotating unit 100, a plate 300, and a cleaning material supply unit 400d. The cleaning material supply unit 400d may include a main body B3 and a plurality of nozzles N1. A length of the main body B3 in the first direction D1 may be longer than a length of the main body B1 (shown in FIG. 1) in the first direction D1. The main body B3 may include a cleaning material generating unit 401 (shown in FIG. 3), a container 402 (shown in FIG. 3), and a pressurizing unit 403 (shown in FIG. 3) inside, like the main body B1 (shown in FIG. 3).

The main body B3 may include a first surface S1-a and a second surface S2-a that are opposite to each other in the third direction D3. The first surface S1-a may be an upper surface of the main body B3, and the second surface S2-a may be a lower surface of the main body B3. A plurality of nozzles N1 may be combined with the second surface S2-a. The plurality of nozzles N1 may be disposed on the second surface S2-a to be spaced apart from each other in the first direction D1. The plurality of nozzles N1 may be configured to receive the cleaning material C from a container 402 inside the main body B3 and spray the cleaning material C onto the surface of the brush 220.

The main body B3 may move in the first direction D1 and in the direction opposite to the first direction D1 along the guide rail GR1, similar to the main body B1. In this way, while the main body B3 moves along the guide rail GR1, the plurality of nozzles N1 combined with the lower surface of the main body B3 may spray the cleaning material C onto the surface of the brush 220, thereby evenly spraying the cleaning material C onto the surface of the brush 220. Although FIG. 10 shows that three nozzles N1 are disposed on the lower surface of the main body B3, the example embodiments are not limited thereto. According to some example embodiments, the number of nozzles N1 disposed on the lower surface of the main body B3 may vary.

In some example embodiments, a width L1 of the brush 220 in the first direction D1 may be greater than a width L2 of the plurality of nozzles N1 in the first direction D1. At this time, the width L2 of the plurality of nozzles N1 in the first direction D1 may be set on the basis of the nozzle N1 disposed at the furthermost edge in the direction opposite to the first direction D1 and the nozzle N1 disposed at the furthermost edge in the first direction D1, among the plurality of nozzles N1 disposed on the second surface S2-a of the main body B3 to be spaced apart from each other in the first direction D1. For example, the width L2 of the plurality of nozzles N1 in the first direction D1 may be set on the basis of a nozzle N1 disposed at a first furthest edge in the first direction D1 and a second nozzle N1 disposed at a second furthest edge in the first direction D1 opposite the first furthest edge. For example, a width L2 of the plurality of nozzles N1 in the first direction D1 may be a length measured in the first direction D1 from an end T1 that protrudes most in the direction opposite to the first direction D1 of the nozzle N1 disposed at the furthermost edge in the direction opposite to the first direction D1 among the plurality of nozzles N1 to an end T2 that protrudes most in the first direction D1 of the nozzle N1 disposed at the furthermost edge in the first direction D1 among the plurality of nozzles N1. For example, a width L2 of the plurality of nozzles N1 in the first direction D1 may be a length measured in the first direction D1 from an end T1 corresponding to a nozzle N1 at the first furthest edge in the first direction D1 to an end T2 corresponding to a nozzle N1 at the second furthest edge opposite the first furthest edge in the first direction D1.

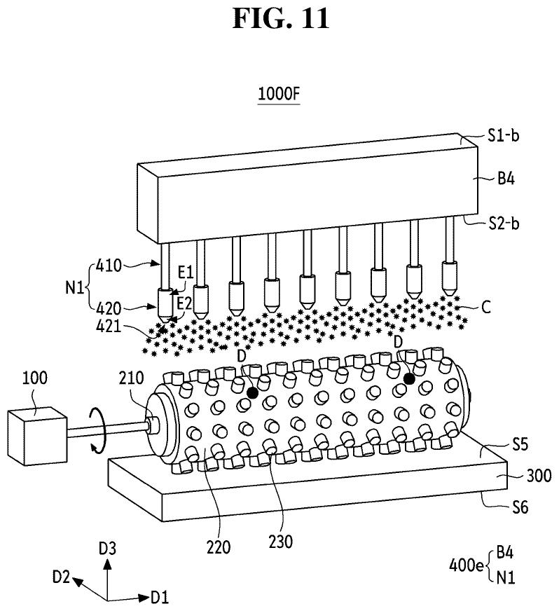

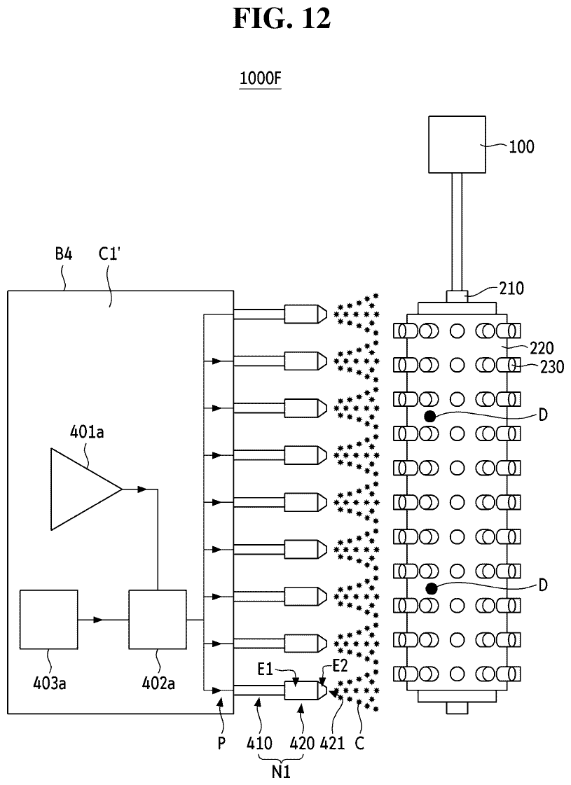

FIGS. 11 and 12 are diagrams for explaining a brush cleaning equipment according to some example embodiments.

A brush cleaning equipment 1000F may include a rotating unit 100, a plate 300, and a cleaning material supply unit 400e. The cleaning material supply unit 400e may include a main body B4 and a plurality of nozzles N1. The cleaning material supply unit 400e may be disposed above the brush core 210 to be opposite to the plate 300 with the brush core 210 interposed therebetween. The main body B4 may include a first surface S1-b and a second surface S2-b that are opposite to each other in the third direction D3. The first surface S1-b may be an upper surface of the main body B4, and the second surface S2-b may be a lower surface of the main body B4. The nozzles N1 may be combined with the second surface S2-b of the main body B4. The nozzles N1 may be disposed on the second surface S2-b to be spaced apart from each other in the first direction D1.

The main body B4 is fixed to the upper part of the brush core 210 so that the second end E2 of each nozzle tip N1, in which the outlet 421 is formed, is spaced apart from the surface of the brush 220 by a predetermined or alternatively desired distance. A cavity C1′ of the main body B4 may include a cleaning material generating unit 401a, a container 402a, and a pressurizing unit 403a. The cavity C1′ of the main body B4 may have a plurality of passages P corresponding to each of the plurality of nozzles N1. The plurality of passages P may be connected to the container 402a. The container 402a may be connected to each of the nozzles N1 corresponding to the corresponding passages through each of the plurality of passages P.

The cleaning material C carried into the inside of the container 402a from the cleaning material supply unit 400e is pressurized by the pressurized gas provided to the container 402a from the pressurizing unit 403a, and may move to the plurality of passages P. Each of the plurality of passages P may provide the cleaning material C to each of the corresponding nozzles N1, and the cleaning material C may be sprayed from each nozzle N1.

The brush core 210, which has obtained a rotational power by the rotating unit 100, rotates around the central axis in the first direction D1 and rubs against the surface of the brush 220 against the first surface S5 of the plate 300. At the same time, the plurality of nozzles N1 may evenly spray the cleaning material C onto the surface of the brush 220. As a result, the cleaning material C collides with the contaminants adsorbed on the surface of the brush 220 to detach the contaminants.

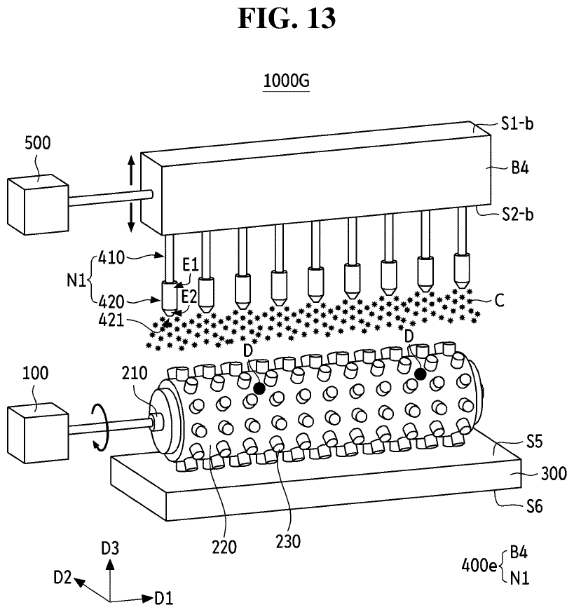

FIG. 13 is a diagram for explaining a brush cleaning equipment according to some example embodiments.

Referring to FIG. 13, a brush cleaning equipment 1000G may further include a conveying unit 500. The conveying unit 500 may be connected to the main body B4. The conveying unit 500 may be configured to provide power that allows the main body B4 to move in the third direction D3 and in a direction opposite to the third direction D3. As a result, the cleaning material supply unit 400e may move in the third direction D3 or in a direction opposite to the third direction D3, while spraying the cleaning material C onto the surface of the brush 220 through the plurality of nozzles N1.

In this way, as the cleaning material supply unit 400 that supplies the cleaning material C to the surface of the brush 220 may move freely in the third direction D3 and in the direction opposite to the third direction D3, the cleaning material C may be targeted and sprayed to the region to which the contaminants are adsorbed among the regions of the surface of the brush 220.

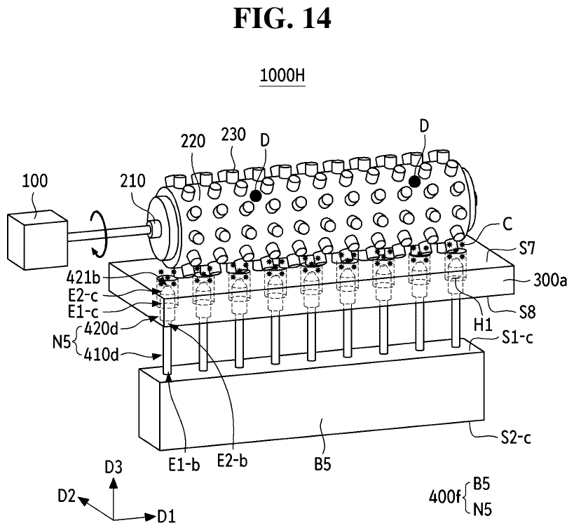

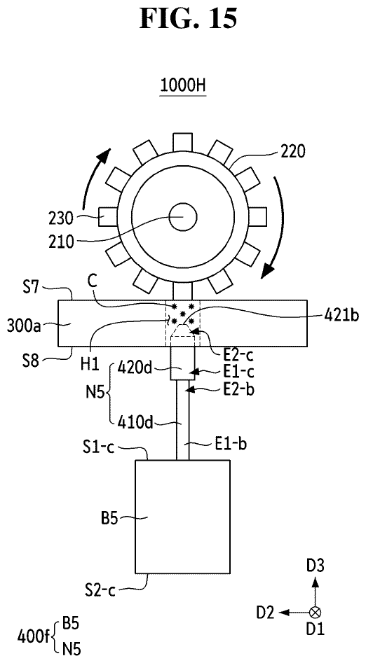

FIGS. 14 and 15 are diagrams for explaining a brush cleaning equipment according to some example embodiments.

A brush cleaning equipment 1000H may include a rotating unit 100, a plate 300a, and a cleaning material supply unit 400f. The rotating unit 100 is connected to the brush core 210, and may provide rotational power so that the brush core 210 may rotate around the first direction D1 as a central axis.

The plate 300a may include a first surface S7 and a second surface S8 that are opposite to each other in the third direction D3. The first surface S7 may be an upper surface of the plate 300a, and the second surface S8 may be a lower surface of the plate 300a. The plate 300a may include (e.g., define) a plurality of holes H1. Each of the plurality of holes H1 may include a shape extending from the first surface S7 to the second surface S8 of the plate 300a. The plurality of holes H1 may extend in the third direction D3, and penetrate the plate 300a in the third direction D3. The plurality of holes H1 may be formed in the plate 300a to be spaced apart from each other in the first direction D1.

The cleaning material supply unit 400f may include a main body B5 and a plurality of nozzles N5. The main body B5 may include a first surface S1-c and a second surface S2-c that are opposite to each other in the third direction D3. The first surface S1-c may be an upper surface of the main body B5, and the second surface S2-c may be a lower surface of the main body B5. The main body B5 may be disposed below the plate 300a. The first surface S1-c of the main body B5 may be disposed to face the second surface S8 of the plate 300a, and the second surface S2-c of the main body B5 may be disposed to be opposite to the second surface S8 of the plate 300a.

The nozzles N5 may be combined with the first surface S1-c of the main body B5. The nozzles N5 may include a nozzle arm 410d and a nozzle tip 420d. A first end E1-b of the nozzle arm 410d may be combined with the main body B5, and a second end E2-b of the nozzle arm 410d may be connected to the nozzle tip 420d. A first end E1-c of the nozzle tip 420d may be combined with the second end E2-b of the nozzle arm 410a, and a second end E2-c of the nozzle tip 420d may face the surface of the brush 220. The second end E2-c of the nozzle tip 420d may be formed with an outlet 421b through which the cleaning material C flows out. The outlet 421b may be formed in the longitudinal direction of the nozzle tip 420d, and may be formed to face the surface of the brush 220. The plurality of holes H1 may be formed in the plate 300a by the number corresponding to the number of the nozzles N5 combined with the main body B5.

The main body B5 may include a cleaning material generating unit 401a (shown in FIG. 12), a container 402a (shown in FIG. 12), a pressurizing unit 403a (shown in FIG. 12), and a plurality of passages (P, shown in FIG. 12) inside, like the main body B4 of FIG. 12. As a result, the cleaning material supply unit 400f may spray the cleaning material C, which is carried into the container 402a through the plurality of nozzles N5, toward the surface of the brush 220 in the third direction D3.

In some example embodiments, as shown in FIG. 15, the main body B5 may be disposed below the plate 300a so that at least a part of a nozzle tip 420d is inserted into the hole H1. As a result, the cleaning material C flowing out from the outlet 421b of the nozzle tip 420d passes through the inside of the hole H1, and may be sprayed to a region placed on a straight line with the hole H1 in the third direction D3 on the surface of the brush 220. As a result, the cleaning material C may be applied on a specific region to which the contaminants are adsorbed among the regions of the surface of the brush 220 to effectively remove the contaminants adsorbed on the surface of the brush 220.

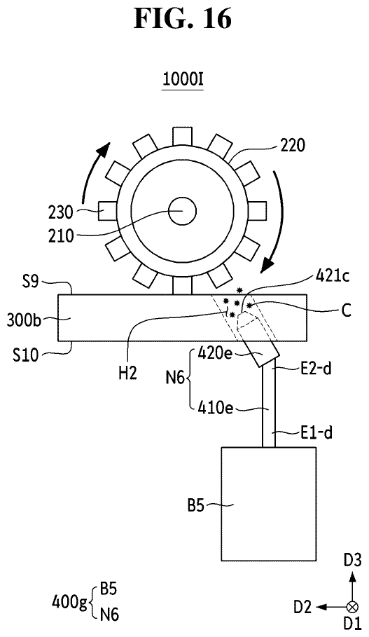

FIG. 16 is a diagram for explaining a brush cleaning equipment according to some example embodiments.

Referring to FIG. 16, a brush cleaning equipment 1000I may include a rotating unit 100 (shown in FIG. 14), a plate 300b, and a cleaning material supply unit 400g. The plate 300b may include a first surface S9 and a second surface S10 that are opposite to each other in the third direction D3. The first surface S9 may be an upper surface of the plate 300b, and the second surface S10 may be a lower surface of the plate 300b. The plate 300b may include a plurality of holes H2. FIG. 16 is a side view of the brush cleaning equipment 1000I, and the plurality of holes H2 may be disposed in the plate 300b to be spaced apart from each other along the first direction D1. The plurality of holes H2 may include a shape that extends from the first surface S9 to the second surface S10 of the plate 300b.

In some example embodiments as depicted in FIG. 15, unlike the configuration in which the holes H1 include a shape extending in the third direction D3 perpendicular to the first surface S7 and the second surface S8 of the plate 300a, the holes H2 formed in the plate 300b may include a tilted shape. For example, the holes H2 may be formed such that an angle between its longitudinal direction and the first surface S9 of the plate 300b is 0 degrees to 90 degrees.

The cleaning material supply unit 400g may include a main body B5 and nozzles N6. The nozzles N6 may each include a nozzle arm 410e and a nozzle tip 420e. The nozzle arm 410e may include a first end E1-d combined with the upper surface of the main body B5, and a second end E2-d connected to the nozzle tip 420a, and may extend in the third direction D3. At least a part of the nozzle tip 420a may be inserted into the hole H2. Accordingly, the nozzle tip 420e may extend in the same direction as the longitudinal direction in which the hole H2 extends.

In this way, as the hole H2, into which at least a part of the nozzle tip 420e from which the cleaning material C flows out is inserted, has a tilted shape with respect to the plate 300b, the cleaning material C may be targeted and sprayed to the region to which contaminants are adsorbed, among the regions of the surface of the brush 220.

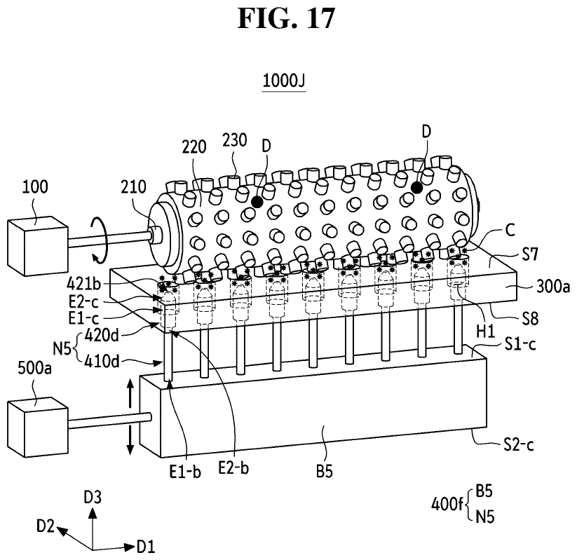

FIG. 17 is a diagram for explaining a brush cleaning equipment according to some example embodiments.

Referring to FIG. 17, a brush cleaning equipment 1000J may further include a conveying unit 500a. The conveying unit 500a may be connected to the main body B5. The conveying unit 500a may be configured to provide a power that allows the main body B5 to move in the third direction D3 and in a direction opposite to the third direction D3. Thus, the cleaning material supply unit 400f may move in the third direction D3 or in a direction opposite to the third direction D3, while spraying the cleaning material C onto the surface of the brush 220 through the plurality of nozzles N5.

For example, the conveying unit 500a may convey the main body B5 in the third direction D3 so that at least a part of the nozzle tip 420d is inserted into the hole H1. Alternatively, the conveying unit 500a may convey the main body B5 in the direction opposite to the third direction D3 so that the nozzle tip 420d is not inserted into the hole H1.

In this way, the conveying unit 500a may freely convey the main body B5 in the third direction D3 or in the direction opposite to the third direction D3, such that the cleaning material C is targeted and sprayed onto the region to which the contaminants are adsorbed, among the regions of the surface of the brush 220.

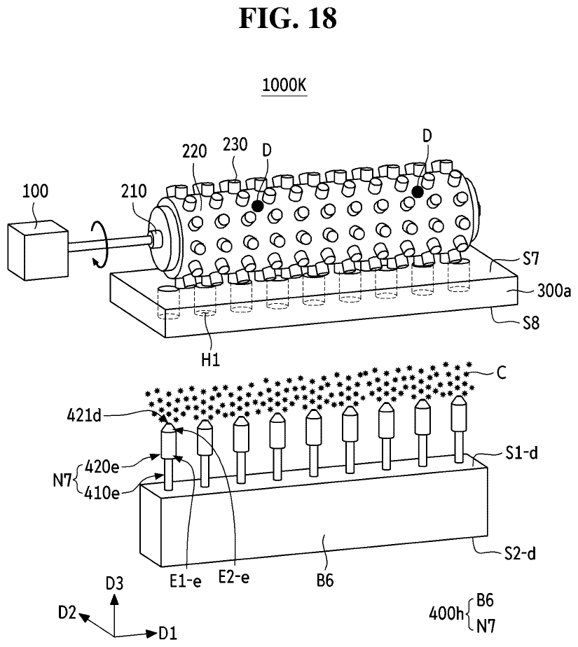

FIG. 18 is a diagram for explaining a brush cleaning equipment according to some example embodiments.

Referring to FIG. 18, a brush cleaning equipment 1000K may include a rotating unit 100, a plate 300a, and a cleaning material supply unit 400h. The cleaning material supply unit 400h may include a main body B6 and a plurality of nozzles N7. Each of the plurality of nozzles N7 may include a nozzle arm 410e and a nozzle tip 420e, and the nozzle tip 420e may include a first end E1-e combined with the nozzle arm 410e, and a second end E2-e opposite to the first end E1-e. An outlet 421d facing the second surface S8 of the plate 300a may be formed at the second end E2-e of the nozzle tip 420a, and the cleaning material C may be sprayed from the outlet 421d.

The cleaning material supply unit 400h may be disposed below the plate 300a. The cleaning material supply unit 400h may be disposed such that the second end E2-e of the nozzle tip 420e is spaced apart from the second surface S8 of the plate 300a by a predetermined or alternatively desired distance. The plurality of nozzles N7 combined with the main body B6 may each correspond to the holes H1 formed in the plate 300a. For example, each of the plurality of nozzles N7 and each of the holes H1 may be disposed on the same line in the third direction D3.

The cleaning material C sprayed from the outlet 421d of the nozzle tip 420e may pass through the inside of the hole H1 corresponding to the nozzle N7, and reach the surface of the brush 220. The cleaning material C that reaches the surface of the brush 220 may remove contaminants adsorbed onto the surface of the brush 220.

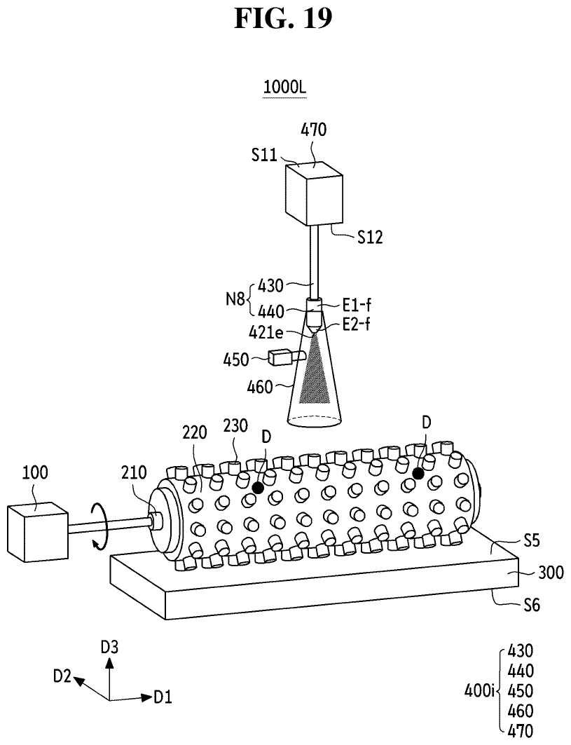

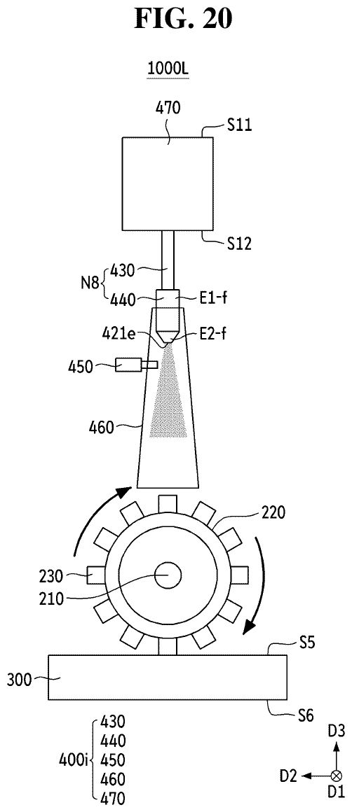

FIGS. 19 and 20 are diagrams for explaining a brush cleaning equipment according to some example embodiments.

A brush cleaning equipment 1000L may include a rotating unit 100, a plate 300, and a cleaning material supply unit 400i. The cleaning material supply unit 400i may include a gas supply unit 470, a nozzle N8, a spark plug 450, and a heat insulator 460.

The gas supply unit 470 may include a first surface S11 and a second surface S12 that are opposite to each other in the third direction D3. The first surface S11 may be an upper surface of the gas supply unit 470, and the second surface S12 may be a lower surface of the gas supply unit 470. A nozzle N8 extending in the third direction D3 may be combined with the lower surface of the gas supply unit 470. The nozzle N8 may include a nozzle arm 430 and a nozzle tip 440. The nozzle tip 440 may include a first end E1-f combined with the nozzle arm 430, and a second end E2-f opposite to the first end E1-f. The second end E2-f may be disposed to face the brush 220. An outlet 421e may be formed at the second end E2-f of the nozzle tip 440. The outlet 421e may be formed in the longitudinal direction of the nozzle tip 440, and may be disposed to face the surface of the brush 220. The insulator 460 may be combined with the nozzle tip 440. The insulator 460 may include an insulator, and may include a shape extending in the third direction D3.

The gas supply unit 470 may supply a flammable gas. For example, the gas supply unit 470 may supply butane. The flammable gas supplied by the gas supply unit 470 may be supplied to the outlet 421e of the nozzle tip 440 through the nozzle arm 430. The spark plug 450 may be combined with the heat insulator 460. The spark plug 450 may perform a flame discharge to ignite the flammable gas provided to the outlet 421e. The flammable gas ignited by the spark plug 450 may diffuse in the third direction D3 along the inside of the heat insulator 460 and reach the surface of the brush 220.

As the brush core 210 which receives rotational power by the rotating unit 100 rotates, the surface of the brush 220 rotating around the first direction D1 as the axis rubs against the upper surface of the plate 300, and at the same time, the flammable gas may reach the surface of the brush 220 and may be applied onto the contaminants adsorbed onto the surface of the brush 220. As a result, the contaminants adsorbed onto the surface of the brush 220 may be effectively removed from the brush 220.

Although some example embodiments of the present disclosure have been described with reference to the accompanying drawings, the present disclosure is not limited to the above example embodiments, but may be implemented in various different forms. A person skilled in the art may appreciate that the present disclosure may be practiced in other concrete forms without changing the technical spirit or essential characteristics of the present disclosure. Therefore, it should be appreciated that the example embodiments as described above is not restrictive but illustrative in all respects.

What is claimed is:

1. A brush cleaning equipment comprising:
a rotating unit configured to rotate a brush core extending in a first direction;
a plate on one side of the brush core and configured to rub against a surface of a brush along a periphery of the brush core in response to the rotation of the brush core; and
a cleaning material supply unit on an other side of the brush core opposite to the plate in a second direction intersecting the first direction, the cleaning material supply unit configured to supply a cleaning material onto the surface of the brush,
wherein the cleaning material supply unit includes,
a main body including a cavity configured to carry the cleaning material; and
a nozzle combined with the main body, the nozzle configured to receive the cleaning material from the main body and spray the cleaning material onto the surface of the brush.

2. The brush cleaning equipment of claim 1, further comprising:
a guide rail extending in the first direction, the guide rail providing a guide such that the main body is configured to move along the guide rail in the first direction.

3. The brush cleaning equipment of claim 2, wherein the guide rail includes a ball screw type guide rail, and the main body is configured to combine with the ball screw type guide rail to move along ball screw type guide rail in the first direction.

4. The brush cleaning equipment of claim 2, wherein
the guide rail includes a first sub-guide rail and a second sub-guide rail spaced apart from each other in a third direction intersecting the first direction and the second direction, and
the first sub-guide rail and the second sub-guide rail each extend in the first direction.

5. The brush cleaning equipment of claim 4, wherein
the main body includes a first surface and a second surface opposite to each other in the third direction,
the main body includes a first wheel mounted on the first surface, and a second wheel mounted on the second surface, and
the main body is configured to move along the guide rail in the first direction such that the first wheel is configured to rotate along the first sub-guide rail and the second wheel is configured to rotate along the second sub-guide rail.

6. The brush cleaning equipment of claim 1, wherein the cleaning material includes dry ice.

7. The brush cleaning equipment of claim 1, wherein the main body includes,
a cleaning material generating unit configured to generate the cleaning material;
a container connected to the cleaning material generating unit, the container configured to receive the cleaning material from the cleaning material generating unit and store cleaning material inside; and
a pressurizing unit configured to pressurize the cleaning material carried into the container, using pressurized gas.

8. The brush cleaning equipment of claim 1, wherein the nozzle includes,
a nozzle arm combined with the main body, and
a nozzle tip including a first end combined with the nozzle arm, and a second end having an outlet defined by the second end, the outlet configured such that the cleaning material flows out through the outlet; and
the outlet is oriented in a longitudinal direction of the nozzle tip.

9. The brush cleaning equipment of claim 8, wherein the nozzle extends in a direction perpendicular to the first direction.

10. The brush cleaning equipment of claim 8, wherein
the plate includes a first surface configured to rub against the surface of the brush, and a second surface opposite to the first surface in the second direction, and
an angle formed between the longitudinal direction of the nozzle and the first surface is between 0 degrees and 90 degrees.

11. A brush cleaning equipment comprising:
a rotating unit configured to rotate a brush core extending in a first direction;
a plate including a first surface and a second surface opposite each other in a second direction intersecting the first direction, the plate configured to rub against a surface of a brush along a periphery of the brush core in response to the brush core rotating; and
a cleaning material supply unit on the second surface, the cleaning material supply unit configured to supply a cleaning material onto the surface of the brush,
wherein the brush is on the first surface,
the plate defines a hole extending from the first surface to the second surface,
the cleaning material supply unit includes,
a main body having a cavity configured to carry the cleaning material, the cavity being on the second surface; and
a nozzle configured to receive the cleaning material from the main body and spray the cleaning material onto the surface of the brush,
the nozzle includes a nozzle arm combined with the main body, and a nozzle tip combined with the nozzle arm, and
the nozzle is configured to spray the cleaning material onto the surface of the brush through the hole.

12. The brush cleaning equipment of claim 11, wherein the main body is on the second surface such that at least a part of the nozzle tip is inserted into the hole.

13. The brush cleaning equipment of claim 11, wherein the nozzle tip includes an outlet, the cleaning material configured to flow from the outlet,
the outlet is oriented in a longitudinal direction of the nozzle tip, and
the nozzle tip is spaced apart from the second surface such that the outlet faces the hole.

14. The brush cleaning equipment of claim 11, wherein an angle formed between a longitudinal direction of the hole and the first surface is between 0 degrees and 90 degrees.

15. A brush cleaning equipment comprising:
a rotating unit configured to rotate a brush core extending in a first direction;
a plate on one side of the brush core, the plate configured to rub against a surface of a brush along a periphery of the brush core in response to the brush core rotating;
a guide rail extending in the first direction, the guide rail on an other side of the brush core opposite to the plate in a second direction intersecting the first direction; and
a cleaning material supply unit configured to supply a cleaning material to the surface of the brush,
wherein the cleaning material supply unit includes,
a main body configured to move along the guide rail, the main body including a cleaning material generating unit, a container configured to carry the cleaning material inside, and a pressurizing unit configured to pressurize the cleaning material carried into the container with pressurized gas; and
a nozzle combined with the main body, the nozzle configured to receive the cleaning material from the container and spray the cleaning material onto the surface of the brush.

16. The brush cleaning equipment of claim 15, wherein
the cleaning material supply unit includes a plurality of nozzles, and
the plurality of nozzles are on a first surface of the main body facing the surface of the brush and the plurality of nozzles are spaced apart from each other in the first direction.

17. The brush cleaning equipment of claim 16, wherein a width of the brush in the first direction is greater than a width of the plurality of nozzles in the first direction.

18. The brush cleaning equipment of claim 15, further comprising:
a conveying unit configured to convey the cleaning material supply unit in the second direction and in a direction opposite to the second direction.

19. The brush cleaning equipment of claim 15, wherein
the guide rail includes a first sub-guide rail and a second sub-guide rail spaced apart in a third direction intersecting the first direction and the second direction, and
each of the first sub-guide rail and the second sub-guide rail extend in the first direction.

20. The brush cleaning equipment of claim 19, wherein
the main body includes a first surface and a second surface opposite to each other in the third direction,
the main body further includes a first wheel mounted on the first surface, and a second wheel mounted on the second surface, and
the main body is configured to move along the guide rail in the first direction such that the first wheel is configured to rotate along the first sub-guide rail, and the second wheel is configured to rotate along the second sub-guide rail.
